(19) United States
(12) Patent Application Publication
(10) Pub. No.: US 2026/0176165 A1
(43) Pub. Date: Jun. 25, 2026

(54) WASTE WATER PURIFICATION SYSTEM

(71) Applicant: KARADENIZ TEKNIK UNIVERSITESI TEKNOLOJI TRANSFERI UYGULAMA VE ARASTIRMA MERKEZI MUDURLUGU, Trabzon (TR)

(72) Inventors: TEOMAN AYHAN, TRABZON (TR); BETUL SARAC, TRABZON (TR); FERIDUN KESKIN, TRABZON (TR); BEDIR UNVER, TRABZON (TR)

(73) Assignee: KARADENIZ TEKNIK UNIVERSITESI TEKNOLOJI TRANSFERI UYGULAMA VE ARASTIRMA MERKEZI MUDURLUGU, Trabzon (TR)

(21) Appl. No.: 18/834,629

(22) PCT Filed: Dec. 15, 2023
(86) PCT No.: PCT/TR2023/051556

§ 371 Date: Jul. 31, 2024

(30) Foreign Application Priority Data
Feb. 27, 2023 (TR) 2023/002148

(51) Int. Cl. C02F 1/28; C02F 1/00; C02F 1/44

(52) U.S. Cl. CPC C02F 1/281; C02F 1/004; C02F 1/283; C02F 1/441

(57) ABSTRACT

A water purification system for minimising energy consumption and low-cost includes: a water line peltier element, a clean water pond, a waste water pond, a drainage pond, a distillation unit, a peltier element in the distillation unit, transparent glass, a clean water line, a heater, a waste water line, a drainage line, a pendant-shaped peltier surface, an impurity pond, a peltier surface on the clean water line and a peltier surface on the waste water line.

### CROSS REFERENCE TO THE RELATED APPLICATIONS

This application is the national phase entry of International Application No. PCT/TR2023/051556, filed on Dec. 15, 2023, which is based upon and claims priority to Turkish Patent Application No. 2023/002148, filed on Feb. 27, 2023, the entire contents of which are incorporated herein by reference.

### TECHNICAL FIELD

The invention relates to a water purification system for obtaining clean water by purifying waste water. The system subject to the invention minimises energy consumption and thereby provides low-cost water purification.

### BACKGROUND

The rapidly increasing world population over the years brings along different problems. The increase in settlements at the same rate, the consumption needs of the rapidly increasing population can be counted among these problems. These situations increase at the same rate as the increasing population. In parallel with the increasing settlements, industrial facilities are also increasing. The uncontrolled release of the materials that turn into waste by using them here also damages the natural environment. This situation causes deterioration of the natural balance as well as it also negatively affects living life. Even nowadays, many living organisms life is under threat. The water polluted by people in places such as industrial plants and houses can be defined as waste water. These waste waters are discharged over time to various surface water, seepage and rainwater and groundwater.

Waste water may have physical, chemical or biological pollution. Pollutants in waste water, in addition to adversely affecting living life, also prevent the systems that need water from working properly. Substances such as gravel, sand or solid particulate pollutants settle to the bottom of the water, allowing mechanical systems to to function properly. These substances cause wear of pumps and pipes in mechanical systems and blockage of ducts and pipes. For this reason, waste water treatment is important [1].

Systems operating with physical, chemical or biological methods are used in the treatment of waste water. Especially in production areas where chemicals are used, many different treatment systems can be preferred. Likewise, for physically contaminated waters, various treatment systems are available. Since the treatment system required by each industry is different, the treatment system suitable for the area used should be determined. Chemical treatment consists of adding various chemicals to the waste water in fast and slow mixing units and precipitating these chemicals by reacting with the pollutants in the waste water. Biological treatment is carried out by biodegradation of domestic or industrial waste water with or without oxygen with the help of bacteria. Physical treatment is the removal of oil and coarse wastes in waste water physically by mechanical processes without using any chemicals or bacteria.

Systems operating by chemical methods work on the principle of converting pollutants dissolved in water into compounds with low solubility as a result of chemical reactions. In particular, it is among the aims of this method to ensure the treatment of suspended substances by turning them into lumps and precipitating them. Three different chemical treatment systems are available. These are coagulation, flocculation and neutralisation processes [2].

One of the leading methods of chemical treatment systems is coagulation and the other is flocculation. Coagulation system is the mixing of coagulant substances into the waste water at the correct pH level and making it ready for floc formation by combining with colloidal and suspended solids in the water. Chemical substances such as lime, aluminium, ferrous sulphate and ferric chloride as well as polyelectrolyte are used during this process. In addition, iron salts, aluminium salts, calcium salts are other preferred chemicals. Ferrous sulphate provides highly effective results in the treatment of manganese and iron; however, the correct amount needs to be adjusted when used in combination with lime. For this reason, the user should know how much iron sulphate and lime to use. High speed mechanical mixers are preferred in order to obtain accurate results from the coagulation process. After this process, flocculation process is applied to mix the water slowly and to combine the particles formed. Flocculation is the process of forming flocs by the combination and collapse of small particles formed as a result of the coagulation process as a result of mixing the waste water at the appropriate speed. After this process, a pool is made to settle the formed lumps. Coagulation, flocculation and settling ponds can be constructed together or separately according to preference [3].

Another chemical treatment system works with neutralisation method. Neutralisation method is a very necessary method for the waste water to reach the appropriate pH value for the environment in which it will be mixed, to have the appropriate pH value before biological treatment and to provide pH values suitable for chemical precipitation processes. The waters used in industrial areas are generally waters with very low or very high pH values. The pH values of these waters should be adjusted before they are reused or mixed with surface water. Because the water that mixes into nature in this way causes damage to living things and disrupts the ecological balance. Therefore, the neutralisation method is used to bring the pH value in the water to the range of 6 to 9. This process can be called as acid and base supplementation process in order to bring the acidic and basic waste water to a pH value compatible with the environment [4].

Activated sludge systems, biofilm systems, stabilisation ponds, aerated lagoons and trickling filters in biological treatment systems is being used. Activated sludge system consists of equalisation, aeration, settling and disinfection units. Systems working according to activated sludge technique, are the most commonly used systems in practice. Stabilisation ponds are simple to operate and do not require much mechanical equipment and are grouped as aerobic, anaerobic and facultative stabilisation ponds. The oxygen required for aerated lagoons is supplied by diffusers or surface aerators. Anaerobic filter; developed as an adaptation of still cell reactors, the filler material used in the form of an anaerobic filter provides the contact surface necessary for biofilm development. Fluidised bed systems; in this system the upflow reactor is partially filled with a carrier material (usually sand). In this reactor, it is aimed to realise the treatment by forming biofilm on sand particles [5].

Treatment by physical methods, which is also called the process of purification from all particles in water, is a preferred method before treatment by chemical methods. It is used for the removal of floating and collapsible substances in water. Although it varies depending on the pollution status of the water to be treated in physical treatment systems and the content of the waste water, it can be grouped under 4 main headings. These are screens, sieves, sand traps and stabilisation [6]. In physical treatment systems; screens, sieves, sand traps and equalisation ponds are preferred as treatment methods.

The screens used in physical treatment systems are generally installed on the flow line of waste water. Depending on the size of the material passed, the spacing of the screens varies. Important features to be considered when selecting this equipment include flow rate, flow characteristics, bar spacing, screening surface and load losses. Manual or automatic cleaning of gratings options are available. Since the characteristics of the preferred screens will vary depending on the waste water content, all the variables needed should be taken into consideration. The sieve used in physical treatment systems is preferred for the separation of smaller sized substances other than the large substances retained in the screens; it is used to reduce the pollution loads of solids entering the treatment system after the screens. These screens can be placed in front of bar screens or behind trickling filters. Sand traps used in physical treatment systems are preferred for the separation of sand in water, which can cause serious damage in the long term. All substances such as sand, gravel, metal and glass, which have a higher density than organic substances in waste water and cannot be biodegraded, are called sand. Balancing is used to prevent organic load fluctuations. This method ensures adequate pH values [7]. In the treatment of water in the systems in question, evaporator apparatus or devices for evaporating water in order to evaporate the water and then condensing apparatus or devices in order to return it back to the liquid state is being used. Since these evaporators and condensers are high energy devices, they increase the energy consumption of simple, fractionated and water spring distillation systems. Due to the high energy consumption in these systems, water treatment costs with these systems are also quite high.

CN101084162A numbered patent application in the state of the art, relates to a liquid processing apparatus and a processing method, the method comprising a distillation process can be used for liquids. This technology can also reduce the energy consumption of hot water heating devices such as water heater tanks. Appropriate cooling measures can be taken according to the output capacity requirements of the distillery. For example, a general refrigerator, a Peltier effect refrigerator, an electric fan or circulating water can be used for cooling. The top cover includes a drainage channel formed by connecting the open conical element to the cylindrical bottom surface in the top cover. This drainage channel is used to collect condensed vapour formed on the inner surface of the top cover. The condensed steam falls into the drainage channel and enters the pipe through the steam outlet and then enters the condenser through the pipe. Furthermore, the technology in question includes a distillation machine. In the patent application a condenser is used. Since this condenser works with high energy, the water treatment method with the device subject to patent application CN101084162A causes high energy consumption; therefore, it increases the cost of water treatment.

Due to the high cost of water treatment with these systems or methods due to the fact that the water treatment systems or methods in the current technique include evaporators or concentrators that cause high energy consumption, it is necessary to make a development that minimises energy consumption and treatment costs in the relevant field.

### SUMMARY

The invention discloses a system for distillation of waste water by evaporation and condensation, which minimises energy consumption. The water purification system comprising: water line peltier element (1), clean water pond (2), waste water pond (3), drainage pond (4), distillation unit (5), peltier element (6) in the distillation unit (5), transparent glass (7), clean water line (8), heater (9), waste water line (10), drainage line (11), pendant-shaped peltier surface (12), impurity pond (13), peltier surface (14) on the clean water line (8) and peltier surface (15) on the waste water line (10).

The object of the invention is to provide a system for the treatment of waste water which minimises energy consumption. In the water purification system, no extra evaporator or condenser is used for the evaporation and subsequent condensation of water, unlike the systems in the prior art. In the invention, the distillation unit (5) is provided with a transparent glass (7) at the top. Thanks to the transparent glass, heating is carried out by utilising the sun rays. Furthermore, the system comprises a peltier element (6) in the distillation unit (5). The peltier element (6) in the distillation unit (5) comprises a pendant-shaped peltier surface (12). The pendant-shaped peltier surface (12) is a cold surface, and when the evaporated water touches the said pendant-shaped peltier surface (12), it condenses due to the coldness of the surface and turns back into liquid. Thus, a waste water purification system that minimises energy consumption thanks to the transparent glass (7) and pendant-shaped peltier surface (12) elements is provided. A further object of the invention is to provide a system for the cost-effective treatment of waste water. In the water purification system, no extra evaporator or condenser is used for the evaporation and subsequent condensation of water; evaporation and condensation processes are provided naturally. In the invention, the transparent glass (7) and the pendant-shaped peltier surface (12) form an energy-efficient system that minimises energy consumption. waste water treatment system is provided. Therefore, there is no need for an extra condenser or evaporator in the present system. A system for the cost-effective treatment of waste water by minimising energy consumption is provided. The invention provides a waste water purification system for the treatment of waste water, which minimises energy consumption and treatment costs.

### BRIEF DESCRIPTION OF THE DRAWINGS

FIG. 1: Isometric view of waste water purification system.

FIG. 2: Front view of the waste water purification system.

FIG. 3: A-A cross-sectional view of the waste water purification system.

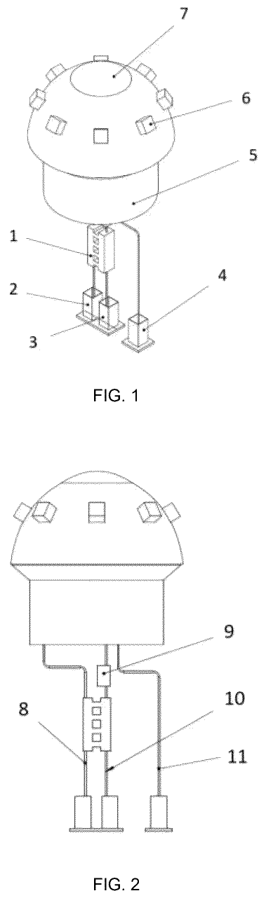

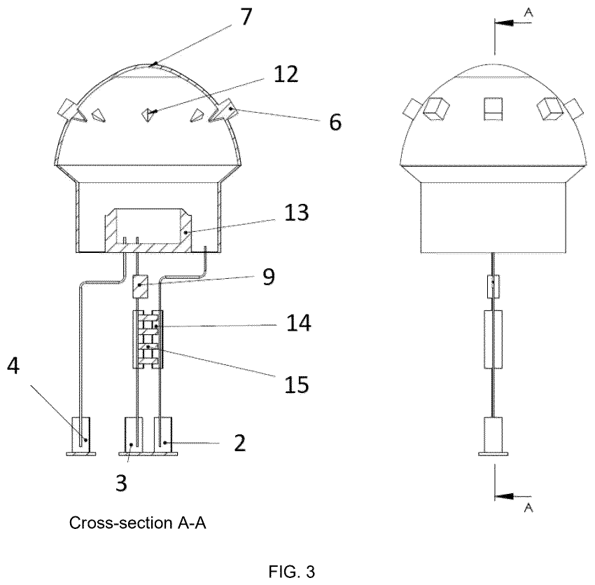

### DESCRIPTION OF REFERENCES

16. Water line peltier element
17. Clean water pond
18. Waste water pond
19. Drainage pond
20. Distillation unit
21. Peltier element in the distillation unit (5)
22. Transparent glass
23. Clean water line
24. Heater
25. Waste water line
26. Drainage line
27. Pendant-shaped peltier surface
28. Impurity pond
29. Peltier surface on the clean water line (8)
30. Peltier surface on the waste water line (10)

### DETAILED DESCRIPTION OF THE EMBODIMENTS

The invention relates to a waste water purification system for distillation of waste water by evaporation and condensation, which minimises energy consumption.

The subject of the invention is a waste water purification system, comprising;
water line peltier element (1) connected to the clean water pond (2) by the clean water line (8) and to the waste water pond (3) by the waste water line (10), providing heating and evaporation of the waste water and cooling and condensation of the clean water, including the peltier surface (14) in the clean water line (8) and the peltier surface (15) in the waste water line (10),
open-top clean water pond (2) for collecting condensed water from the distillation unit, connected to the water line peltier element (1) by the clean water line (8),
open-top waste water pond (3), connected to the water line peltier element (1) by the waste water line (10), containing the dirty water which is the source of the water vapour to the distillation unit (5),
open-top drainage pond (4) connected to the distillation unit (5) by a drainage line (11), for the return of waste not evaporated in the distillation unit (5),
closed, insulated, distillation unit (5), in which the impurity pond (13) is positioned, with transparent glass (7) at the top, connected to the water line peltier element (1) and the clean water pond (2) via the clean water line (8), connected to the water line peltier element (1) and the waste water pond (3) via the waste water line (10), and connected to the drainage pool (4) via the drainage line (11), performing the distillation process,
at least one peltier element (6) in the distillation unit (5) positioned on the distillation unit (5), which allows the evaporated water to cool and condense,
at least one pendant-shaped peltier surface (12) positioned on the inner surface of the distillation unit (5), which condenses water vapour into water droplets,
impurity pond (13) located in the distillation unit (5), where non-evaporated impurities in the waste water accumulate,
at least one peltier surface (14) on the clean water line (8), which is positioned in the water line peltier element (1), which cools and condenses the clean water,
at least one peltier surface (15) on the waste water line (10), which is positioned in the water line peltier element (1), which provides heating and evaporation of waste water.

The water line peltier element (1) provides heating and evaporation of waste water and cooling and condensation of clean water. The clean water pond (2) is an open top pond where the condensed water from the distillation unit (5) accumulates. The waste water pond (3) is the pond which will contain the waste water which is the source of the water vapour to the distillation unit (5). The drainage pond (4) is an open-top pond for the return of non-evaporated waste from the distillation unit (5). Distillation unit (5), where the vapour of the waste water is a closed, insulated unit that allows distillation. The peltier element (6) on the distillation unit (5) is located on the distillation unit (5) and cools the water vapour to condense the vapour. The transparent glass (7) is a glass positioned at the top of the distillation unit (5), which allows sunlight to penetrate into the distillation unit (5), thereby increasing the temperature of the distillation unit (5). The clean water line (8) is the line that transfers the purified water from the distillation unit (5) to the clean water pond (2). The waste water line (10) is the line that transfers the water to be treated in the waste water pond (3) to the distillation unit (5). The drainage line (11) is the line for transferring the substances that do not evaporate in the distillation unit (5) to the drainage pond (4). The pendant-shaped peltier surface (12) is the cold surface for condensing water vapour in the distillation unit (5). Impurity pond (13) is the pond where non-evaporative impurities in the waste water accumulate. The peltier surface (14) on the clean water line (8) ensures that the water vapour is cooled and condensed. The peltier surface (15) in the waste water line (10) provides heating and evaporation of the waste water. The peltier element (6) and the pendant-shaped peltier surface (12) in the distillation unit (5) subject to the invention are monoblock.

The water purification system further comprises a heater (9). The heater (9) is positioned on the waste water line between the water line peltier element (1) and the distillation unit (5). The heater subject to the invention accelerates the evaporation of the waste water to be treated before it reaches the distillation unit (5).

Method of operation of a waste water purification system, comprising the steps of;
ix. taking the waste water to be treated into the waste water pond (3),
x. dropping the pressure of the distillation unit (5) to zero by vacuum,
xi. rising the waste water which taken into the waste water pond (3) under the influence of open air pressure,
xii. rising waste water in the waste water line (10), evaporation through the peltier surface (15) in the waste water line (10) and filling of the evaporated water into the distillation unit (5),
xiii. condensing the clean water vapour filled the distillation unit (5) by contact with the pendant-shaped peltier surface (12),
xiv. descending of the condensed clean water to the surface of the distillation unit (5) and filling of the polluting substances in the waste water into the impurity pond (13),
xv. filling of the substances accumulated in the impurity pond (13) into the drainage pond (4) via the drainage line (11),
xvi. filling the clean water accumulated in the distillation unit (5) to clean water pond (2) by contacting the peltier surface (14) in the clean water line through the clean water line (8).

In the process step (iv) of the subject of the invention method, a heater (9) is used to accelerate evaporation.

In the subject of the invention system, the pressure of the distillation unit (5) is reduced to zero by vacuum. In the distillation unit (5), the pressure is reduced to zero, allowing the water to evaporate at low temperatures. Thus, water vapour is obtained from waste water by evaporation. The lower boiling point (volatility) of water allows it to leave the impurity pond (13) faster than other substances. The evaporated water starts to condense when it comes into contact with or close to the peltier element (6) in the distillation unit (5). In the invention, the water dripping from the peltier element (6) in the distillation unit (5) starts to flow into the clean water line (8) in the distillation unit (5) instead of the impurity pond (13). Although some condensed clean water flows into the impurity pond (13), it evaporates and rises again in a short time. Therefore, the continuously evaporating water will rise and drip down through the peltier element (6) in the distillation unit (5). When descending, it will not flow into the impurity pond (13) due to the positioning of the peltier element (6) in the distillation unit (5).

### REFERENCES

[1] ATIK SU ve ÖZELLİKLERİ. (2020, July 6). Haliç çevre Laboratuvari. https://haliccevre.com/atik-su-ve-ozellikleri/
[2] Atik Su Aritimi Yöntemleri Nelerdir? (2021, March 12). Aba Yayin. https://abayayin.com/atik-su-aritimi-yontemleri-nelerdir/
[3] Koagülasyon-Liberta Kimya ve Mühendislik. (n.d.). https://www.libertakimya.com.tr/koagulasyon/
[4] Nötralizasyon Tanki|GESU Aritma Sistemleri. (2021, December 14). Gesu çevre Teknolojileri. https://www.gesu.com.tr/plastik-imalatlar/notralizasyon-tanki.html
[5] Biyolojik Aritmanin Temelleri|Artemis Aritim. (n.d.). https://www.artemisaritim.com/biyolojik-aritmanin-temelleri
[6] Atiksu aritiminin temel prosesleri. (n.d.). https://www.aerzen.com/tr/uygulamalar/suve-atiksu-aritma/atiksu-aritma-uezerine-tavsiyeler/atik su-aritma-prosesleri.html
[7] Fiziksel Su Aritma Sistemleri, Nature Life Su Aritma. (n.d.). http://www.suaritmasistem.net/fiziksel-su-aritma-sistemleri.php.

What is claimed is:

1. A water purification system for minimising energy consumption and low-cost, comprising:
a water line peltier element connected to a clean water pond by a clean water line and to a waste water pond by a waste water line, providing heating and evaporation of waste water and cooling and condensation of clean water, comprising a first peltier surface in the clean water line and a second peltier surface in the waste water line,
an open-top clean water pond for collecting condensed water from a distillation unit, connected to the water line peltier element by the clean water line,
an open-top waste water pond, connected to the water line peltier element by the waste water line, containing dirty water configured to be a source of the water vapour to the distillation unit,
an open-top drainage pond connected to the distillation unit by a drainage line, for a return of waste not evaporated in the distillation unit,
the distillation unit, being closed and insulated, in which an impurity pond is positioned, with transparent glass at top, connected to the water line peltier element and the open-top clean water pond via the clean water line, connected to the water line peltier element and the open-top waste water pond via the waste water line, and connected to the drainage pond via the drainage line, performing a distillation process,
at least one peltier element in the distillation unit positioned on the distillation unit, and configured to allow evaporated water to cool and condense,
at least one pendant-shaped peltier surface positioned on an inner surface of the distillation unit, and configured to condenses water vapour into water droplets,
an impurity pond located in the distillation unit, where non-evaporated impurities in the waste water accumulate,
at least one first peltier surface on the clean water line, positioned in the water line peltier element, and configured to cool and condense the clean water, and
at least one second peltier surface on the waste water line, positioned in the water line peltier element, and configured to provide heating and evaporation of the waste water.

2. The water purification system according to the claim 1, further comprising: a heater positioned on the waste water line, between the water line peltier element and the distillation unit, accelerating an evaporation of the waste water to be treated before the waste water reaches the distillation unit.

3. The water purification system according to the claim 1, wherein the at least one peltier element and the at least one pendant-shaped peltier surface in the distillation unit are of monoblock construction.

4. A method of operation of the water purification system according to claim 1, comprising:
i. taking the waste water to be treated into the open-top waste water pond,
ii. dropping a pressure of the distillation unit to zero by vacuum,
iii. rising the waste water which is taken into the open-top waste water pond under an influence of open air pressure,
iv. rising the waste water in the waste water line, evaporation through the second peltier surface in the waste water line and filling of the evaporated water into the distillation unit,
v. condensing the clean water vapour filled the distillation unit by contact with the at least one pendant-shaped peltier surface,
vi. descending condensed clean water to a surface of the distillation unit and filling polluting substances in the waste water into the impurity pond,
vii. filling the polluting substances accumulated in the impurity pond into the open-top drainage pond via the drainage line, and
viii. filling the clean water accumulated in the distillation unit to the open-top clean water pond by contacting the first peltier surface in the clean water line through the clean water line.

5. The method according to claim 4, wherein in the process step (iv), a heater is used to accelerate the evaporation.

6. The water purification system according to the claim 2, wherein the at least one peltier element and the at least one pendant-shaped peltier surface in the distillation unit are of monoblock construction.

7. The method according to the claim 4, wherein the water purification system further comprises: a heater positioned on the waste water line, between the water line peltier element and the distillation unit, accelerating an evaporation of the waste water to be treated before the waste water reaches the distillation unit.

8. The method according to the claim 4, wherein in the water purification system, the at least one peltier element and the at least one pendant-shaped peltier surface in the distillation unit are of monoblock construction.
